(19) United States
(12) Patent Application Publication
(10) Pub. No.: US 2009/0314631 A1
(43) Pub. Date: Dec. 24, 2009

(54) Magnetron With Electromagnets And Permanent Magnets

(75) Inventors: Mark A. Bernick, White Oak, PA (US); Richard Newcomb, McKeesport, PA (US)

Correspondence Address: THE WEBB LAW FIRM, P.C., 700 KOPPERS BUILDING, 436 SEVENTH AVENUE, PITTSBURGH, PA, 15219, US

(73) Assignee: ANGSTROM SCIENCES, INC., Duquesne, PA (US)

(21) Appl. No.: 12/486,797

(22) Filed: Jun. 18, 2009

Related U.S. Application Data
(60) Provisional application No. 61/132,423, filed on Jun. 18, 2008.

(51) Int. Cl. C23C 14/35

(52) U.S. Cl. 204/192.1; 204/298.17

(57) ABSTRACT

A magnet assembly for a magnetron sputtering device having circular, linear or other types of planar targets including two permanent magnets and an electromagnet, e.g., electromagnetic coil between the permanent magnets associated with a sputtering target of a target assembly. An electrical control circuit is arranged to selectively adjust at least the current level and the direction of current to the electromagnet to alter the magnetic fields of the magnet assembly thereby encompassing the entire portions of the sputtering target, including the extreme inner and outer portions of the sputtering target to optimize the target uniformity and the sputtered film uniformity on a substrate. Methods for operating the magnet assembly of the magnetron sputtering devices, for optimizing the target utilization and sputtered film uniformity on a substrate, and for operating the magnetron sputtering process in a reactive gas environment to form an insulating or dielectric thin film are also provided.

### CROSS-REFERENCE TO RELATED APPLICATION

This application claims the benefit of U.S. Provisional Application No. 61/132,423, entitled “Magnetron With Electromagnets And Permanent Magnets”, filed on Jun. 18, 2008, which is hereby incorporated by reference.

### BACKGROUND OF THE INVENTION

1. Field of the Invention

This invention relates to a magnet assembly for a magnetron sputtering device. More specifically, the invention relates to a magnet assembly that includes one or more electromagnets and permanent magnets wherein the magnetic fields of the electromagnets are selectively changed to maximize target utilization and sputtered film uniformity on a substrate.

2. Description of Related Art

A typical magnetron sputtering device includes a vacuum chamber having an electrode contained therein, wherein the electrode includes a cathode portion, an anode portion and a sputtering target. In operation, a vacuum is drawn in the vacuum chamber followed by the introduction of a process gas into the chamber. Electrical power supplied to the electrode produces an electronic discharge, which ionizes the process gas and produces charged gaseous ions from the atoms of the process gas. The ions are accelerated and retained within a magnetic field formed over the target, and are propelled toward the surface of the target which is composed of the material sought to be deposited on a substrate. Upon striking the target, the ions dislodge target atoms from the target, which are then deposited upon the substrate. By varying the composition of the target and/or the process gas, a wide variety of substances can be deposited on various substrates. The result is the formation of an ultra-pure thin film deposition of target material on the substrate.

The circular magnetron has long been used for both the development of thin films as well as the production of smaller products which can be coated in a stationary position below the cathode. Although the uniformity is acceptable for many products, there are many occasions when the user has to develop a coating mask to help achieve tight uniformity requirements. Also, the circular magnetron is susceptible to the build-up of dielectric films on the very outer diameter or in the center where there is traditionally no sputter erosion of the target.

Although the circular magnetron has its advantages over the planar or linear magnetrons, the shape of the magnetic field which determines everything from field uniformity and deposition rate to target utilization may still be optimized further to improve the performance of the sputtering application.

Stationary profiled magnets can be used to control the shape of the magnetic field which optimizes the performance of the sputtering application. U.S. Pat. Nos. 5,736,019 and 6,171,461, which are hereby incorporated by reference, relate to circular magnetrons and linear magnetrons which use stationary profiled magnets in an attempt to overcome under-utilization of target material. These patents disclose magnetron sputtering electrodes that include several profiled permanent magnets which have a top portion with an apex positioned adjacent a target supporting surface in the cathode body. The permanent magnet generates magnetic flux lines which form enclosed-looped magnetic tunnels adjacent to the front sputtering surfaces of the target. These profiled magnets generally result in optimum utilization of target materials at a reasonable rate of deposition.

Even though the magnet assemblies of the above prior art may, in some instances, increase target utilization and produce a much more uniform field, there is still a need in the art to provide a magnet assembly in a circular magnetron sputtering device, linear magnetron sputtering device, or in a magnetron sputtering device having any other type of planar target wherein both the target utilization and the sputtered film uniformity on a substrate are optimized even further than that attained by the sputtering devices of the prior art.

It is, therefore, desirable to provide a magnet assembly for a magnetron sputtering device that selectively alters the magnetic fields and the speed in which the magnetic fields of the magnet assemblies are altered so as to optimize the target utilization and the sputtered film uniformity on a substrate.

### SUMMARY OF THE INVENTION

The present invention provides for a magnetron sputtering device that includes a cathode body defining a magnet receiving chamber, a target assembly including a sputtering target adjacent to the cathode body, and a magnet assembly received within the magnet receiving chamber. The magnet assembly includes a plurality of magnets having at least two permanent magnets and at least one electromagnet arranged between the two permanent magnets for selectively altering the magnetic field of the magnet assembly so as to encompass the entire portions of the sputtering target including the extreme inner and outer portions of the sputtering target of the target assembly. The electromagnet may be an electromagnet coil. The magnetron sputtering device, which may be linear or circular, may also include one or more electrical control circuits for adjusting the dwell time, the current level or intensity of the current, the direction of the current to the electromagnet, and the speed in which the magnetic field is altered.

The present invention also provides for a method for optimizing the target utilization and sputtered film uniformity on a substrate. The steps include providing a magnetron sputtering device as previously discussed, selectively altering at least the current level and the direction of current to the electromagnet to alter the magnetic field of the magnet assembly, and selectively adjusting the dwell time, the current level, the direction of the current to the electromagnet, and the speed in which the magnetic field is altered.

### BRIEF DESCRIPTION OF THE DRAWINGS

FIG. 1 is an elevational view of a magnet assembly for a magnetron sputtering device made in accordance with a first embodiment of the present invention;

FIG. 2 is an elevational view of a magnet assembly for a magnetron sputtering device made in accordance with a second embodiment of the present invention;

FIG. 3 is a sectional side view of an electrode assembly of a circular magnetron sputtering device including a magnet assembly of the present invention;

FIG. 3A is a sectional side view of the magnet assembly of FIG. 3 illustrating the N-S and S-N poles of permanent magnets of the magnet assembly;

FIG. 4 is a sectional plan view taken along line IV-IV of FIG. 3;

FIG. 5A is a schematic of section V shown in FIG. 3A illustrating an example of a magnetic field created when no current or power is supplied to an electromagnetic coil of the magnet assembly of the present invention;

FIG. 5B is a schematic of section V shown in FIG. 3A illustrating an example of a magnetic field created when current or power is applied in a first direction to the electromagnetic coil of the magnet assembly of the present invention to confine the electrons at an extreme inner region of a target surface;

FIG. 5C is a schematic of section V shown in FIG. 3A illustrating an example of a magnetic field created when current or power is applied to the electromagnetic coil in a reverse direction of FIG. 5B to confine the electrons at an extreme outer region of the target surface;

FIG. 6 is a sectional plan view of a electrode assembly of a linear magnetron sputtering device including the magnet assembly of the present invention;

FIG. 7 is a sectional perspective view of an electrode assembly of a linear magnetron sputtering device including the magnet assembly of the present invention;

FIG. 8 illustrates an electrical control circuit for the magnet assembly of the present invention represented in FIG. 1;

FIG. 9 illustrates an electrical control circuit for the magnet assembly of the present invention represented in FIG. 2;

FIG. 10A is a plan view of a schematic illustrating the erosion pattern of a target surface when a prior art magnet assembly is used in a linear magnetron sputtering device;

FIG. 10B is a view taken along lines A-A of FIG. 10A;

FIG. 11A is a plan view of a schematic illustrating the erosion pattern of a target surface when the magnet assembly of the invention is used in a linear magnetron sputtering device;

FIG. 11B is a view taken along lines B-B of FIG. 11A;

FIG. 12A is a plan view of a schematic illustrating the erosion pattern of a target surface when a prior art magnet assembly is used in a circular magnetron sputtering device;

FIG. 12B is a sectional view taken along lines C-C of FIG. 12A;

FIG. 13A is a plan view of a schematic illustrating the erosion pattern of a target surface when the magnet assembly of the invention is used in a circular magnetron sputtering device;

FIG. 13B is a view taken along lines D-D of FIG. 13A;

FIG. 14 is a sectional view of a substrate or part schematically illustrating sputtered film uniformity on the substrate utilizing the magnet assembly of the present invention;

FIG. 15 is a sectional view of a substrate or part schematically illustrating target non-uniformity on the substrate utilizing a prior art magnet assembly of a magnetron sputtering device; and

FIG. 16 is a schematic view of a sputtering system made in accordance with the present invention.

### DETAILED DESCRIPTION OF THE INVENTION

The present invention will be described with reference to the accompanying drawings where like reference numbers correspond to like elements. The present invention is directed to a magnetron sputtering device having a circular, a linear, or any other type of planar target.

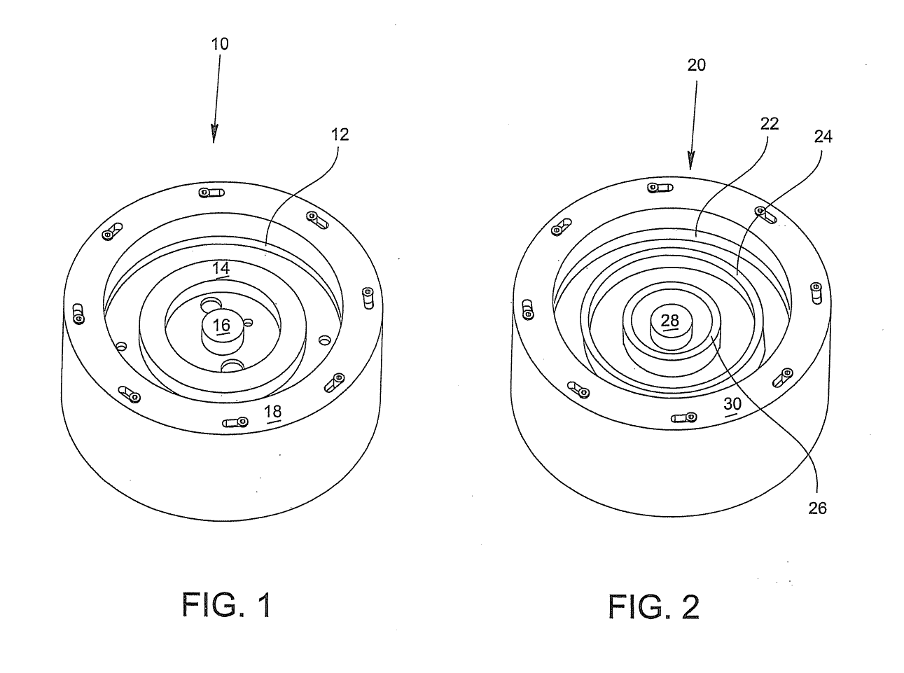

FIG. 1 illustrates a magnet assembly 10 of a first embodiment of the present invention and includes a first ring-shaped magnet 12 which is a permanent magnet, a second ring-shaped magnet 14 which is an electromagnet, and a center magnet 16 which is a permanent magnet. Magnets 12, 14, and 16 are supported in a cathode body 18, more about which is discussed herein below.

FIG. 2 illustrates a magnet assembly 20 of a second embodiment of the present invention and includes a first ring-shaped magnet 22 which is a permanent magnet, a second ring-shaped magnet 24 which is an electromagnet, a third ring-shaped magnet 26 which is an electromagnet, and a center magnet 28 which is a permanent magnet. Magnets 22, 24, 26, and 28 are supported in a cathode body 30, more about which is discussed herein below.

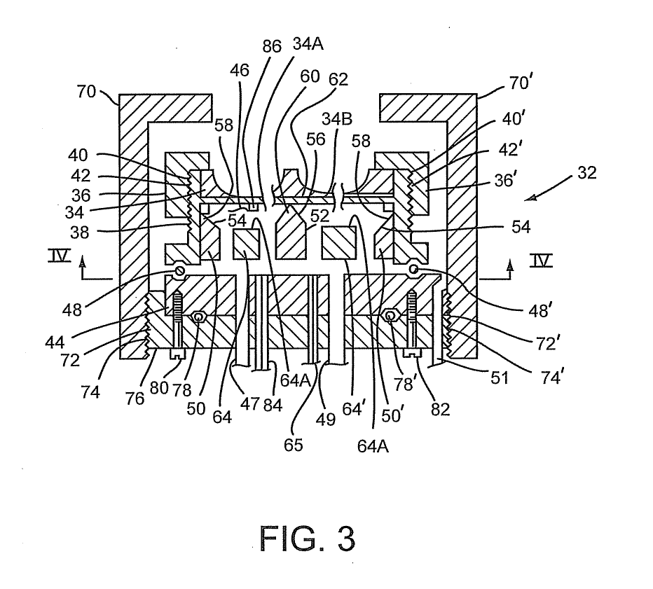

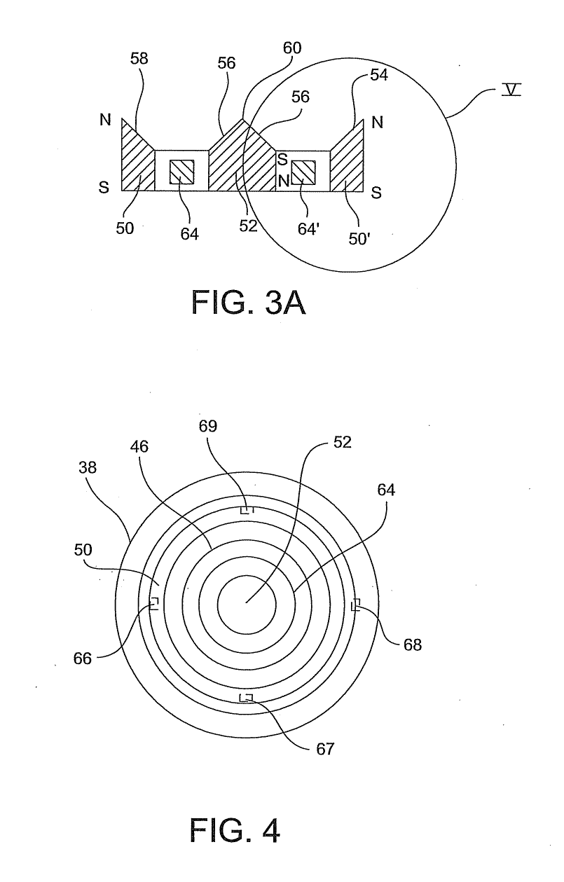

FIG. 3 provides a sectional view of an electrode assembly 32 for a circular magnetron sputtering device and includes a circular sputtering target 34 of a target assembly. Target 34 is held in place by an annular or ring-shaped clamping ring including elements 36 and 36′ due to sectioning, and which will be referred hereinafter as clamping ring 36. Clamping ring 36 also functions as a cathode shield. As stated, electrode assembly 32 is part of a circular magnetron sputtering device and is similar to the electrode assembly disclosed in the above U.S. Pat. No. 6,171,461, the teachings of which are hereby incorporated by reference in its entirety.

Still referring to FIG. 3, circular target 34 is adjacent to a cathode body 38 and is held in place against cathode body 38 by clamping ring 36 via clamping ring threads 40 shown as clamping ring threads 40 and 40′ due to sectioning and hereinafter referred to as clamping ring threads 40. Clamping ring threads 40 mate with cathode body threads shown as cathode body threads 42 and 42′ due to sectioning and hereinafter referred to as cathode body threads 42. The cathode body 38 and clamping ring 36 define a target receiving recess having a depth which is adapted to receive target 34 having varying thicknesses. As disclosed in the '461 patent, the interspace between target clamping ring 36 and the top of cathode body 38 which retains target 34 is variable simply by turning clamping ring 36 and causing clamping ring threads 42 on the interior circumference of clamping ring 36 to travel a greater or lesser distance along cathode body threads 42 located on the exterior circumference of cathode body 38. This also allows for easy removal and replacement of target 34, and further, easily accommodates interchanging target 34 with other targets having different thicknesses. Target 34 is shown in FIG. 3 as having target surfaces 34A and 34B which are broken. It is to be appreciated that the erosion pattern of target 34 of FIG. 3, represented by target surfaces 34A and 34B, is generally similar to that shown in FIGS. 11A and 11B of the present invention, more about which is discussed herein below.

Still referring to FIG. 3, cathode body 38 cooperates with an insulator plate 44 to form a water chamber or magnet receiving chamber 46, which is made watertight via an O-ring seal interposed therebetween. The O-ring seal is shown in FIG. 3 as elements 48 and 48′ due to sectioning, but simply constitutes an O-ring seal, which will hereinafter be referred to as an O-ring 48. Contained within water chamber 46 is an outer annular or ring-shaped magnet which is shown as elements 50 and 50′ due to sectioning, which will be referred to hereinafter as a ring magnet 50. Ring magnet 50 is preferably a permanent magnet. The top of ring-shaped magnet 50 is shown as having an upper section having an inclined plane sloping downwardly and inwardly. Also contained within water chamber 46 is a center magnet 52 which is generally circular in form. Center magnet 52 is preferably a permanent magnet. The top of center magnet 52 includes a downwardly and outwardly sloped inclined plane. Magnets 50 and 52 include tips 54 and 56, respectively, each having apexes 58 and 60, respectively, which are positioned adjacent a target supporting surface 62 of the cathode body 38. Even though magnets 50 and 52 are shown as having a profiled surface, it is to be appreciated that in the invention, these magnets 50 and 52 may have flat upper surfaces.

With continued reference to FIG. 3, a second annular or ring-shaped magnet 64 is positioned between the first ring magnet 50 and the center magnet 52. The magnet 64 is shown in FIG. 3 as elements 64 and 64′ due to sectioning, but simply constitutes a ring magnet which will hereinafter be referred to as annular ring magnet 64. Annular ring magnet 64 is preferably an electromagnet, e.g., an electromagnetic coil. Electric current is supplied to electromagnet 64 via a power cable line 65 located to the right of a water inlet supply 47 in FIG. 3. Even though the upper surfaces 64A of electromagnet 64 are flat, it is to be appreciated that these upper surfaces 64A may include tips and apexes similar to that shown for magnets 50 and 52. In an embodiment of the invention, the upper surfaces 64A of electromagnet 64 are flat and the upper surfaces of permanent magnets 50 and 52 are profiled, similar to that shown in FIG. 3.

As shown in FIG. 4, within water chamber 46 are spacers 66, 67, 68 and 69 which function to permit a small space between outer ring magnet 50 and cathode body 38 so that cooling water may flow around ring magnet 50 in a manner disclosed in the aforesaid '461 patent.

Referring again to FIG. 3, electrode assembly 32 further includes a ring-shaped anode shield 70 shown as element 70 and 70′ due to sectioning and hereinafter referred to as anode shield 70. The anode shield 70 includes retaining threads, appearing as elements 72 and 72′ due to sectioning, and hereinafter referred to as anode shield retaining threads 72. Anode shield retaining threads 72 are disposed about the interior circumference of anode shield 70 and threadably engage base plate threads appearing as elements 74 and 74′ due to sectioning, and hereinafter referred to as base plate threads 74. Base plate threads 74 are disposed about the exterior circumference of a base plate 76. Similar to the cathode shield, the distance between anode shield 70 and clamping ring 36 is fully adjustable simply by threading anode shield 70 to a greater or lesser degree along base plate 76. Interposed between insulator plate 44 and base plate 76 is an O-ring for sealing. The O-ring is shown in FIG. 3 as 78 and 78′ due to sectioning, but is simply the same O-ring and will be referred to hereinafter as an O-ring 78. Insulator plate 44 is affixed to base plate 76 via a plurality of screws about the circumference of base plate 76, as represented by screws 80 and 82.

In operation, electric current is supplied to electrode assembly 32 via a power cable 84 which provides a direct connection to cathode body 38 via a screw 86. Electrode assembly 32 further includes an ionizing gas inlet supply line 51, through which ionizing gas is introduced into the interstitial space between clamping ring 36 and anode shield 70. Ionized gas is supplied through the supply line 51 into the electrode assembly 32 and travels up along the target surface 34A of target 34 for the sputtering operation in a manner well-known to those skilled in the art.

FIG. 4 is a sectional plan view taken along line IV-IV of FIG. 3 showing cathode body 38 and water chamber 46 formed therein. Outer ring magnet 50, annular ring magnet 64 and center magnet 52, respectively, are shown located within the water chamber 46. With reference to FIG. 3, water enters chamber 46 via the water inlet supply 47 and exits via a water outlet 49 to efficiently cool the target 34.

Referring to FIG. 3A, since magnets 50 and 52 are permanent magnets, the poles will remain as indicated with the N-S poles attracting. However, the N-S positions of magnets 50 and 52 can vary. Because magnet 64 is an electromagnet, the poles can be reversed and the intensity of the magnetic fields of magnet 64 can be varied. The electromagnet 64 may be a typical electromagnet known in the art, such as a wire coil having current passing therethrough. In this arrangement for the magnet assembly of the invention, which includes ring-shaped permanent magnet 50, annular ring electromagnet 64 and center permanent magnet 52, annular ring electromagnet 64 may be controlled such that the magnetic fields sweep the apex to apply a uniform coating on a substrate. That is, the electromagnet 64 may be operated as to alter the magnetic field of the magnet assembly so as to encompass the entire portions of the sputtering target 34 including the extreme inner and outer portions of the sputtering target 34 of the target assembly.

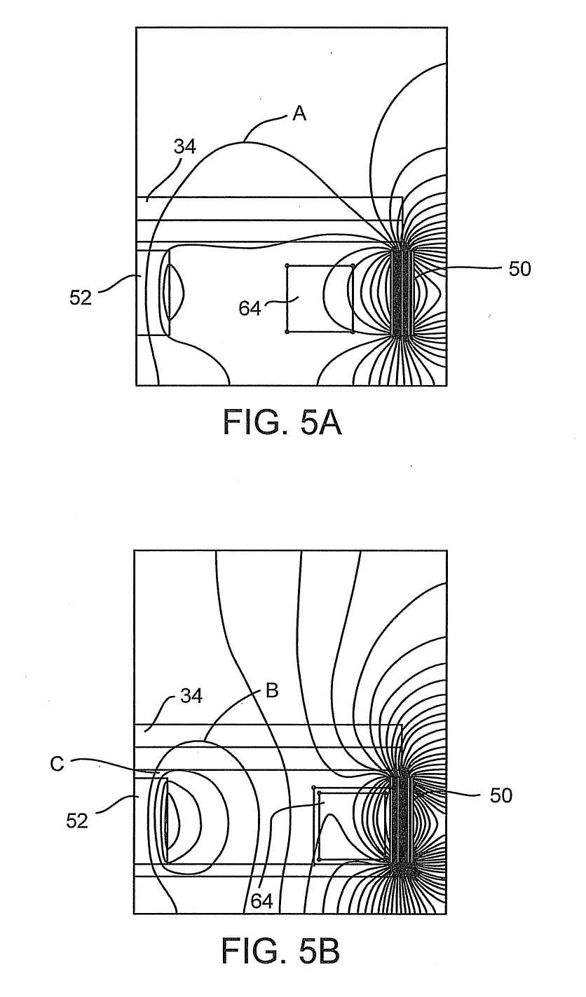

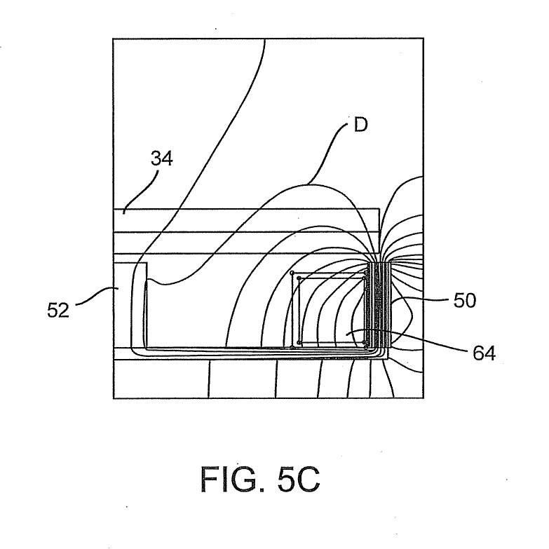

FIGS. 5A through 5C show schematics of section V shown in FIG. 3A illustrating various examples of magnetic flux lines produced from the operation of the magnetron sputtering device of the present invention. Although FIGS. 5A through 5C show the magnetic flux lines using un-profiled magnets 50 and 52, target utilization and uniformity may be improved when profiled magnets are used in the magnet assembly of the invention. Further, the electromagnet 64 may be located at various positions between magnets 50 and 52 as shown in FIGS. 5A-5C. An example of the magnetic flux lines produced as a result of not operating the electromagnet 64 relative to the permanent magnets 50 and 52 is shown in FIG. 5A. That is, FIG. 5A illustrates the magnetic field created by the inner permanent magnet 52 and the outer permanent magnet 50 when no current or power is applied to the electromagnetic coil 64 of the magnet assembly of the invention. Curve A represents the field of sputtering. FIG. 5B illustrates an example of a magnetic field created when the current or power is applied in a first direction to the electromagnetic coil 64 of the magnet assembly of the invention. The magnetic field is driven forward toward the inner permanent magnet 52 to confine the electrons at an extreme inner region of the target surface of target 34. The field of sputtering is indicated at B, and a zero axial field is indicated at C. The zero axial field C is where the sputtering occurs. FIG. 5C illustrates an example of a magnetic field created when the current or power is applied to the electromagnetic coil 64 in a second direction which is a reverse current direction of FIG. 5B. The result is that the magnetic field is driven away from the inner permanent magnet 52 and toward the outer permanent magnet 50 to confine the electrons at an extreme outer region of the target surface of target 34. A zero axial field is indicated at D where the sputtering occurs.

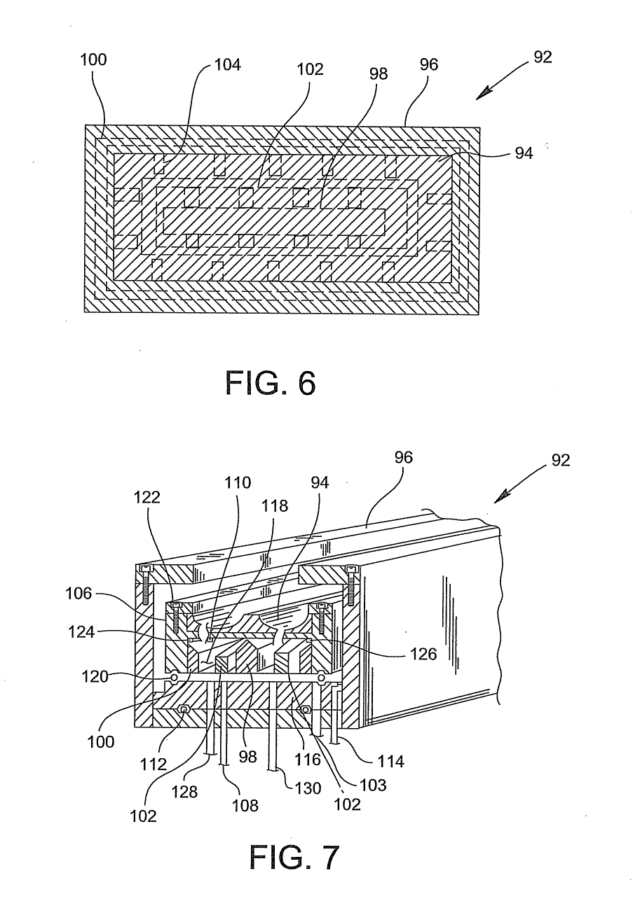

FIG. 6 shows a sectional plan view of a linear electrode assembly 92. Electrode assembly 92 is part of a linear magnetron sputtering device and is similar to the electrode assembly for the linear magnetron sputtering device disclosed in the above U.S. Pat. No. 6,171,461, the teachings of which are hereby incorporated by reference in their entirety. The linear magnetron sputtering device includes a linear sputtering target 94 of a target assembly. Linear sputtering target 94 is adjacent to an anode shield 96. Also shown in FIG. 6 in phantom is a center magnet 98, which is a permanent magnet, a perimeter magnet 100, which also is a permanent magnet, and a rectangular-shaped electromagnet 102 which surrounds the center magnet 98. A series of water diverters 104 extends perpendicularly from the center magnet 98 within the water chamber which is behind target 94 in FIG. 6.

FIG. 7 is a sectional perspective view of the linear electrode assembly 92. The water diverters 104 (shown in FIG. 6) set up a turbulent flow which provides uniform cooling in linear electrode assembly 92 during operation. Electric current is supplied to the cathode body 106 via a power cable 108, which is retained to the cathode body 106 via a screw 110. An O-ring 112 functions in the same manner as O-ring 78 of FIG. 3. An ionizing gas inlet 114 in FIG. 7 functions in the same manner as ionizing gas inlet supply 51 of FIG. 3 to provide the same flow of process gas over the target surface 94 from all 360 degrees. Electric current is supplied to the rectangular-shaped electromagnet 102 via a power cable 103, which is located to the left of gas inlet 114 in FIG. 7. Shown in FIG. 7 are center magnet 98, perimeter magnet 100 and rectangular-shaped electromagnet 102. Center magnet 98 has the same inclined plane as center magnet 52 of FIG. 3, and perimeter magnet 100 has the same inclined plane as permanent magnet ring 50 of FIG. 3. An insulator plate 116 and cathode body 106 cooperate to form a water chamber 118 which is rendered watertight by an O-ring seal 120. Target 94 is retained on cathode body 106 via a target clamping ring 122. Spacers 124 and 126 function in the same manner as spacers 66, 67, 68 and 69 of FIG. 4. A water inlet supply 128 and a water outlet 130 function in the same manner as water inlet supply 47 and water outlet 49 of FIG. 3.

The outer perimeter permanent magnet 100, the center permanent magnet 98 and the rectangular-shaped electromagnet 102 function in a manner similar to the permanent magnets 50 and 52 and electromagnet ring 64 of FIG. 3. In this arrangement for the magnet assembly of the invention, which includes outer perimeter permanent magnet 100, the center permanent magnet 98, and the rectangular-shaped electromagnet 102 can be controlled such that the magnetic fields may sweep the apex to apply a uniform coating on a substrate. That is, the electromagnet 102 may be operated as to alter the magnetic field so as to encompass the entire portions of the sputtering target 94, including the extreme inner and outer portions of the sputtering target 94 of the target assembly. Examples of the magnetic fields created by the magnet assembly of FIGS. 6 and 7 are similar to those illustrated in FIGS. 5A through 5C. As stated hereinabove, the upper surfaces of permanent magnets 98 and 100 may be flat instead of pointed. FIG. 7 illustrates target 94 as being broken. It is to be appreciated that the erosion pattern of target 94 is generally similar to that shown in FIGS. 11A and 11B, more about which is discussed herein below.

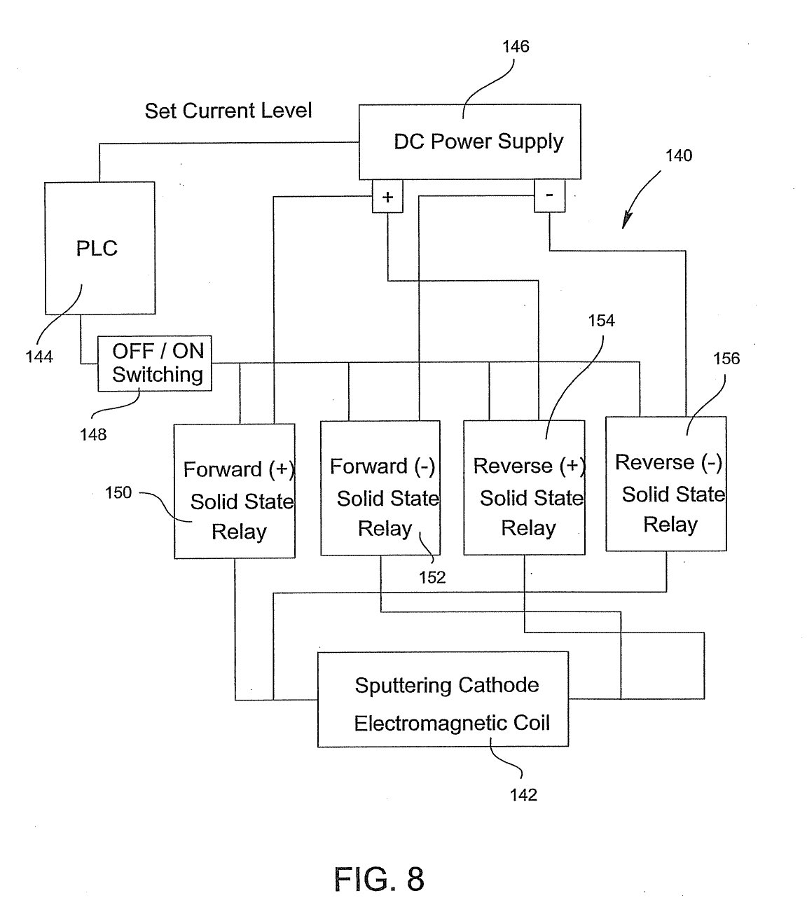

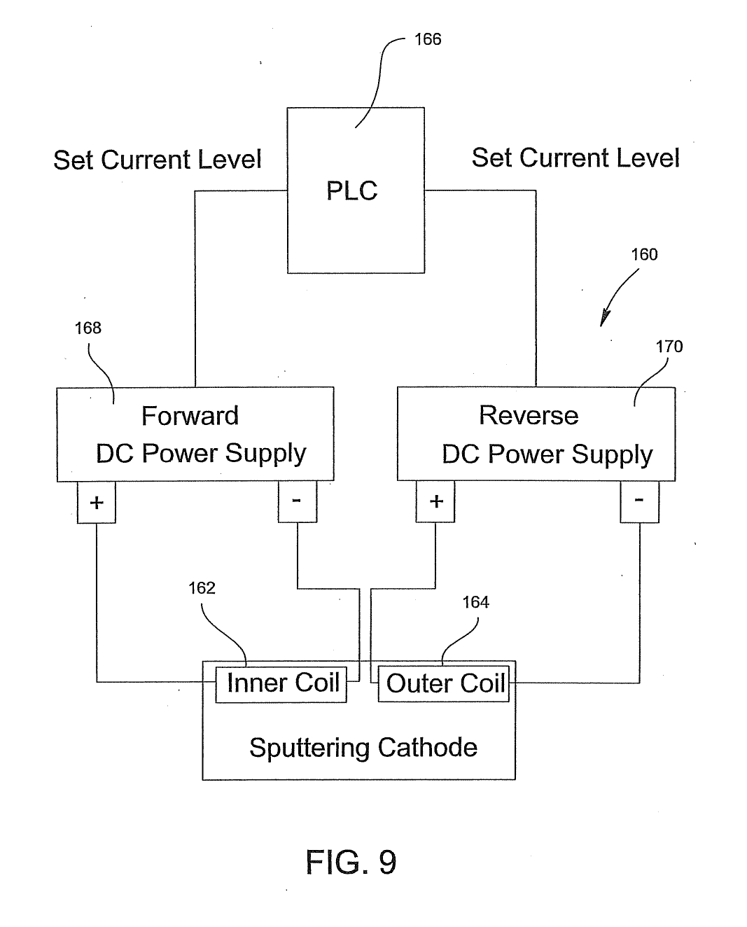

The magnet assembly 10 of FIG. 1 and the magnet assembly 20 of FIG. 2 may be used in the circular electrode assembly 32 of FIG. 3 or in the linear electrode assembly 92 of FIG. 6. Regardless of the type of magnet assembly that may be used in the circular electrode assembly 32 of FIG. 3 or in the linear electrode assembly 92 of FIG. 6, the magnet assembly preferably will include a center permanent magnet, at least one electromagnet, and an outer permanent magnet. This magnet assembly may be operated via an electrical control circuit similar to that shown in FIG. 8 or 9.

FIG. 8 illustrates an electrical control circuit 140 which may be used, for example, with the magnet assembly 10 of FIG. 1. Electrical control circuit 140 includes a sputtering cathode electromagnetic coil 142. A PLC 144 delivers a set current level to a DC power supply 146 and an on/off switch 148 is used to selectively direct a current in a first or forward direction to electromagnetic coil 142 via the DC power supply 146 and solid state relays 150 and 152, or to direct a current in a reverse direction to electromagnetic coil 142 via DC power supply 146 and solid state relays 154 and 156. As discussed hereinabove, when the current is driven in a first or forward direction to electromagnetic coil 142, the magnetic field which is created is similar to that illustrated in FIG. 5B wherein the electrons are confined to the extreme inner region of the target surface of a target to encompass the extreme inner region or portion of the sputtering target. When current is driven in a reverse direction to electromagnetic coil 142, the magnetic field which is created is similar to that illustrated in FIG. 5C wherein the electrons are confined to the extreme outer region of the target surface of the target to encompass the extreme outer region or portion of the sputtering target.

FIG. 9 illustrates an electrical control circuit 160 which may be used, for example, with the magnet assembly 20 of FIG. 2. Electrical control circuit 160 includes an inner electromagnetic coil 162 and an outer electromagnetic coil 164. A PLC 166 is used to set the current level for a forward DC power supply 168 and to set the current level for a reverse DC power supply 170. The forward DC power supply 168 is used to deliver a current in a first or forward direction to the inner electromagnetic coil 162 in order to confine the electrons to the extreme inner region of the target surface of a target to encompass the extreme inner region of the sputtering target, similar to that illustrated in FIG. 5B. The reverse DC power supply 170 is used to deliver a current in a reverse direction to the outer electromagnetic coil 164 in order to confine the electrons to the extreme outer region of the target surface to encompass the extreme outer region of the sputtering target of a sputtering cathode, similar to that illustrated in FIG. 5C.

As stated hereinabove, the magnet assembly 10 of FIG. 1 and the magnet assembly 20 of FIG. 2 may be used in either the circular sputtering device of FIG. 3 or in the linear sputtering device of FIG. 6. A control circuit similar to that illustrated in FIG. 8 may be used with the magnet assembly 10 of FIG. 1 and a control circuit similar to that of FIG. 9 may be used with the magnet assembly 20 of FIG. 2. The PLC of the electrical control circuits may be further programmed to accommodate either a circular sputtering device or a linear sputtering device in order to obtain one or more objects of the invention including maximizing target utilization and sputtered film uniformity on a substrate.

The circular electrode assembly 32 of FIG. 3, the linear electrode assembly 92 of FIG. 6, and the control hardware described above, operate in the same process environment as the circular or linear cathode disclosed in the aforesaid U.S. Pat. Nos. 5,736,019 and 6,171,461. It is not necessary to provide specific process alterations including, but not limited to, the vacuum chamber gas composition, the vacuum chamber pressure, the power to the cathode, and the cooling water flow to the cathode. The electrical control circuits 140 and 160 of FIGS. 8 and 9, respectively, include a PLC, solid state relays and one or more DC power supplies which are capable of providing the required current and voltage to the electromagnetic coil 142 or electromagnetic coils 162 and 164.

To achieve optimum target utilization for the electrode assemblies 32 and 92 of FIGS. 3 and 6, respectively, the PLC and relays of the electrical control circuits 140 and 160 of FIGS. 8 and 9, respectively, may be used to vary the direction and intensity of the DC current to the electromagnetic coil 142 or coils 162 and 164. The magnetic field models of FIGS. 5A through 5C illustrate that under correct conditions the magnetic fields of the cathode may be altered by the direction and the intensity of the current flow to the coil. By varying both the intensity and the direction of the current, it is possible for the magnetic field to encompass the extreme outer and inner portions of the target surface as shown in FIGS. 5B and 5C, respectively, as well as any point in between. Once the current level has been defined to sputter the extremities of the target surface, the operator may then make iterations between these positions so that all areas between the extremities are equally sputtered. Because the outer extremity of the target has a longer racetrack or electron confinement area then the inner extremity, it may be generally necessary to have the magnetic field maintain a longer residence or dwell time, becoming increasingly quicker as the magnetic field is altered to approach the inner racetrack or magnetic confinement region.

To achieve maximum uniformity, the PLC of the electrical control circuits 140 and 160 of FIGS. 8 and 9, respectively, may be initially programmed to operate as described herein above. Through the testing of sputtered films, the operator may then increase the residence or dwell time of the magnetic field in any specific target area adjacent to where the formed thin film has not yet reached its required thickness. Conversely, the operator may decrease the residence or dwell time of the magnetic field in any specific target area adjacent to where the formed thin film has exceeded its required thickness.

To achieve the best results when operating the electrode assemblies 32, 92 of FIGS. 3 and 6, respectively, in a reactive gas environment or when the process time is very short, the PLC of the electrical control circuits 140 and 160 of FIGS. 8 and 9, respectively, may be programmed to move the magnetic fields at very fast times. The frequency of moving the magnetic field from the outer to the inner extremities and back again, can be as fast as 20 Hz or higher. When reactively sputtering the target to form insulating films, there may be a build-up of an insulating film on the target surface. This insulating layer can lead to arcing and excessive debris when the magnetic field is then moved so that this region of the target can be sputtered. By quickly moving the magnetic field, it is possible to reduce this build-up so that the impact of the formed layer is negligible and there are no observed arcs or generation of debris resulting from the arcs. To achieve the optimum uniformity for quick, short process times, it may be advisable to also move the magnetic field quickly so that any variations of the formed film are smoothed by the averaging of many cycles over the target surface.

Methods for operating a magnetron sputtering device including the magnet assembly 10 or 20 of FIGS. 1 and 2, respectively of the invention are also provided. Also, methods for optimizing the target utilization and sputtered film uniformity on a substrate of the circular magnetron sputtering device including the magnet assembly of the invention and for optimizing the target utilization and sputtered film uniformity on a substrate of a magnetron sputtering device including the magnet assembly of the invention are also provided, as well as methods of operating a sputtering process in a reactive gas environment to form an insulating or dielectric thin film. The magnetron sputtering device may be a circular sputtering device or a linear sputtering device.

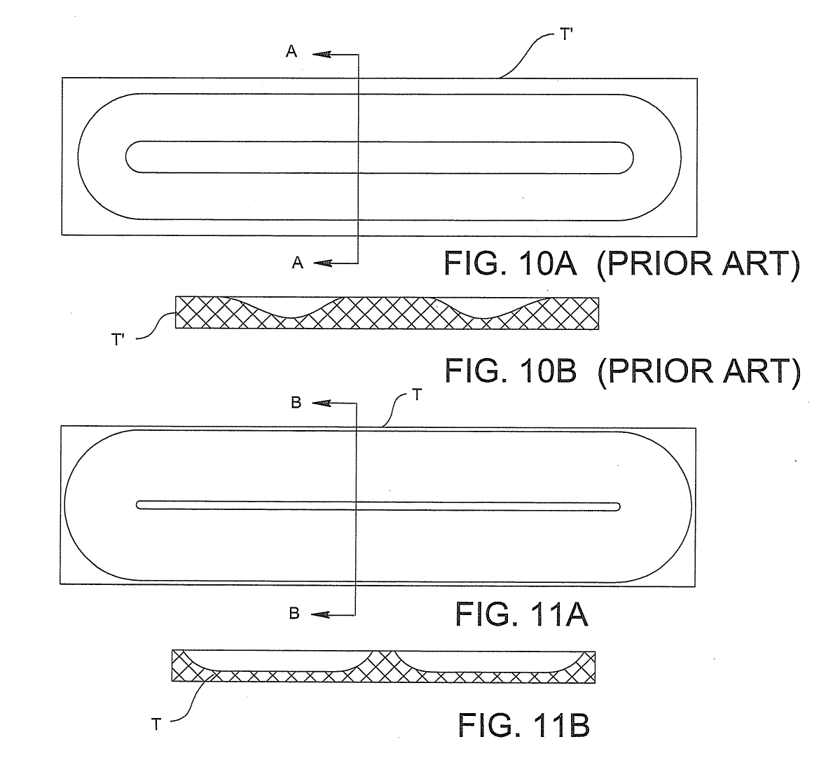

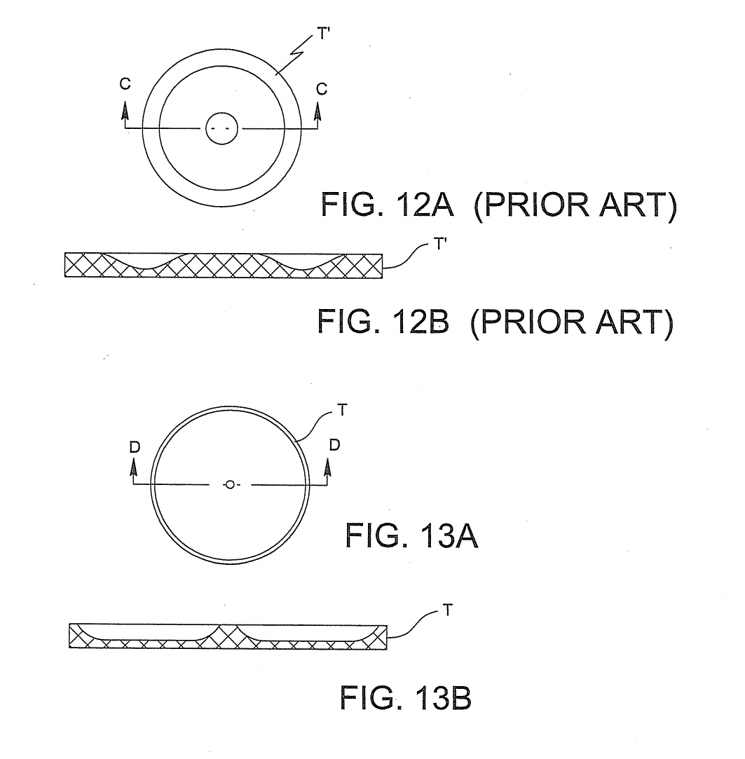

FIGS. 10A-10B and 12A-12B illustrate an erosion pattern for a target T′ when a prior art magnet assembly is used in a linear and circular magnetron sputtering device, respectively. FIGS. 11A-11B and 13A-13B illustrate an example of an erosion pattern for a target T when a magnet assembly of the invention similar to magnet assemblies 10 and 20 of FIGS. 1 and 2, respectively, is used in the linear magnetron sputtering device of FIG. 3 and in the circular magnetron sputtering device of FIG. 6. As shown in FIGS. 11A-11B and 13A-13B, the eroded surfaces of the target T and the middle surface area are wider and flatter than those of the target T′ of the prior art shown in FIGS. 10A-10B and 12A-12B. It is to be appreciated that the eroded surfaces of the target T′ of FIGS. 12A and 12B are generally similar to those shown in the above discussed U.S. Pat. Nos. 5,736,019 and 6,171,461.

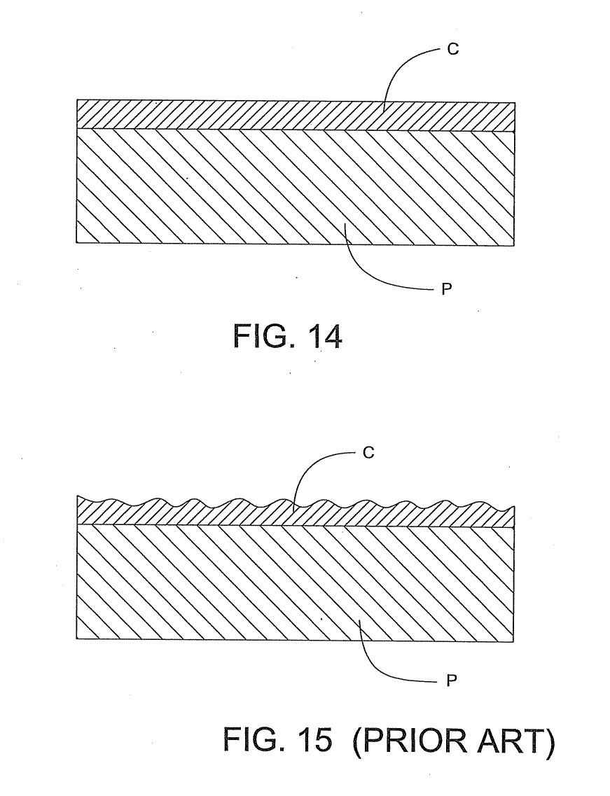

As stated hereinabove, the magnet assembly of the invention includes one or more electromagnets and permanent magnets wherein the magnetic fields of the electromagnets are selectively changed to maximize target utilization and sputtered film uniformity on a substrate. FIG. 14 shows a substrate or part P with a film or coating C, thereby illustrating sputtered film uniformity as a result of the magnet assembly of the invention. FIG. 15 shows a substrate or part P coated with a film or coating C, thereby illustrating target non-uniformity as a result of the magnet assembly of the prior art.

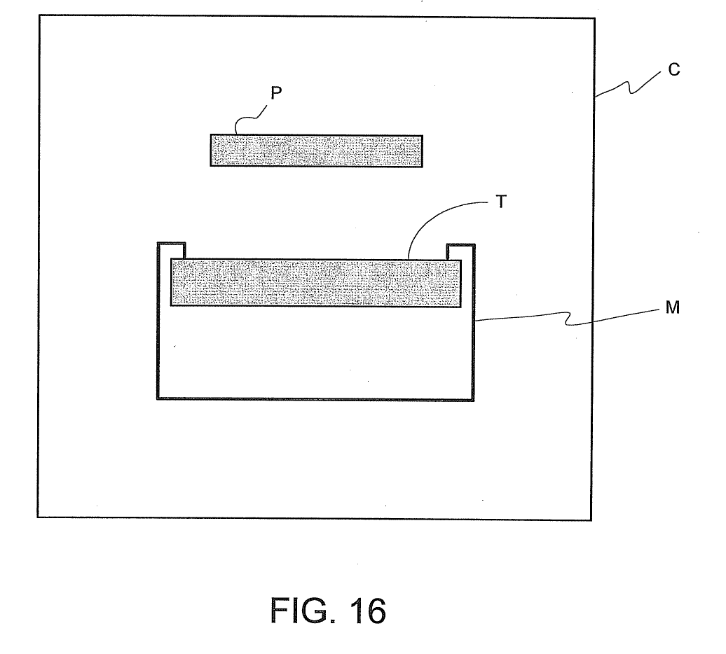

FIG. 16 shows a schematic drawing of a sputtering system made in accordance with the present invention, wherein the substrate P is placed within a chamber C with one of the above identified targets T and one of the above-identified magnet assemblies M generally designated as M.

The present invention has been described with reference to the preferred embodiments. Obvious modifications and alterations will occur to others upon reading and understanding the preceding detailed description. It is intended that the invention be construed as including all such modifications and alterations.

The invention claimed is:

1. A magnetron sputtering device, comprising:
a cathode body defining a magnet receiving chamber;
a target assembly including a sputtering target adjacent to the cathode body; and
a magnet assembly received within the magnet receiving chamber, the magnet assembly comprising a plurality of magnets including at least two permanent magnets and at least one electromagnet arranged between the at least two permanent magnets for selectively altering at least the magnetic field of the magnet assembly so as to encompass the entire portions of the sputtering target, including the extreme inner and outer portions of the sputtering target of the target assembly.

2. The device of claim 1, wherein the magnet assembly further includes an electrical control circuit for selectively adjusting the dwell time, the current level, the direction of the current to the electromagnet, and the speed in which the magnetic field is altered so as to encompass the entire portions of the sputtering target, including the extreme inner and outer portions of the sputtering target of the target assembly.

3. The device of claim 1, wherein the magnetron sputtering device is selected from the group consisting of a circular magnetron sputtering device and a linear magnetron sputtering device.

4. The device of claim 1, wherein the magnet assembly comprises an electromagnet arranged between two permanent magnets.

5. The device of claim 1, wherein the magnet assembly comprises a permanent first magnet, a permanent second magnet, and a permanent center magnet positioned therebetween, and wherein a first electromagnet is positioned between the first magnet and the center magnet and a second electromagnet is positioned between the center magnet and the second magnet.

6. The device of claim 1, wherein the electromagnet comprises an electromagnetic coil.

7. A method for operating a magnetron sputtering device, the steps comprising:
providing a cathode body defining a magnet receiving chamber;
providing a target assembly including a sputtering target adjacent to the cathode body;
providing a magnet assembly received within the magnet receiving chamber and comprised of a plurality of magnets including at least two permanent magnets and at least one electromagnet arranged between the at least two permanent magnets; and
selectively altering at least the current level and the direction of current to the electromagnet to alter the magnetic field of the magnet assembly so as to encompass the entire portions of the sputtering target, including the extreme inner and outer portions of the sputtering target of the target assembly.

8. The method of claim 7, the steps further including:
providing an electrical control circuit for selectively adjusting the dwell time, the current level, the direction of the current to the electromagnet, and the speed at which the magnetic field is altered.

9. The method of claim 7, wherein the magnetron sputtering device is selected from the group consisting of a circular magnetron sputtering device and a linear magnetron sputtering device.

10. A method for optimizing the target utilization and sputtered film uniformity on a substrate of a magnetron sputtering device, the steps comprising:
providing a cathode body defining a magnet receiving chamber;
providing a target assembly including a sputtering target adjacent to the cathode body;
providing a magnet assembly received within the magnet receiving chamber and comprised of a plurality of magnets including at least two permanent magnets and at least one electromagnet arranged between the at least two permanent magnets; and
selectively altering at least the current level and the direction of current to the electromagnet to alter the magnetic field of the magnet assembly so as to encompass the entire portions of the sputtering target, including the extreme inner and outer portions of the sputtering target of the target assembly.

11. The method of claim 10, the steps further including:
providing an electrical control circuit for selectively adjusting the dwell time, the current level, the direction of the current to the electromagnet, and the speed at which the magnetic field is altered.

12. The method of claim 10, wherein the magnetron sputtering device is selected from the group consisting of a circular magnetron sputtering device and a linear magnetron sputtering device.

13. A method of operating a sputtering process in a reactive gas environment to form an insulating or dielectric thin film, the steps comprising:
providing a cathode body defining a magnet receiving chamber;
providing a target assembly including a sputtering target adjacent to the cathode body;
providing a magnet assembly received within the magnet receiving chamber and comprising a plurality of magnets including at least two permanent magnets and at least one electromagnet between the two permanent magnets; and
selectively altering at least the current level and the direction of the current to the electromagnet to alter the magnetic field of the magnet assembly so as to encompass the entire portions of the sputtering target including the extreme inner and outer portions of the sputtering target of the target assembly.

14. The method of claim 13, the steps further including:
providing an electrical control circuit for selectively adjusting the dwell time, the current level, the direction of the current to the electromagnet, and the speed in which the magnetic field is altered so as to encompass the entire portions of the sputtering target including the extreme inner and outer portions of the sputtering target.

15. The method of claim 13, wherein the sputtering process is a circular sputtering process.

16. The method of claim 13, wherein the sputtering process is a linear sputtering process.

17. A sputtering system comprising:
a substrate;
a cathode body defining a magnet receiving chamber;
a target assembly including a sputtering target adjacent to the cathode body; and
a magnet assembly received within the magnet receiving chamber, the magnet assembly comprising a plurality of magnets including at least two permanent magnets and at least one electromagnet arranged between the at least two permanent magnets for selectively altering at least the magnetic field of the magnet assembly so as to encompass the entire portions of the sputtering target, including the extreme inner and outer portions of the sputtering target of the target assembly, wherein material of the sputtered target is deposited onto the substrate such that target utilization and sputtered film uniformity on a substrate are enhanced.
